(19) United States
(12) Patent Application Publication
(10) Pub. No.: US 2024/0347680 A1
(43) Pub. Date: Oct. 17, 2024

(54) ARRANGEMENT, METHOD FOR ASSEMBLING AN OPTOELECTRONIC COMPONENT AND OPTOELECTRONIC COMPONENT

(71) Applicant: ams-OSRAM International GmbH, Regensburg (DE)

(72) Inventors: Michael Zitzlsperger, Regensburg (DE); Hansjörg Schöll, Bad Abbach (DE)

(21) Appl. No.: 18/579,474

(22) PCT Filed: Jul. 21, 2022
(86) PCT No.: PCT/EP2022/070471

§ 371 Date: Jan. 15, 2024

(30) Foreign Application Priority Data
Jul. 29, 2021 (DE) 10 2021 119 709.0

(51) Int. Cl. H01L 33/54; H01L 33/00; H01L 33/48; H01L 33/56

(52) U.S. Cl. CPC H01L 33/54; H01L 33/005; H01L 33/483; H01L 33/56; H01L 2933/005

(57) ABSTRACT

In an embodiment an arrangement includes an optoelectronic component having a radiation passage surface and a housing top surface, which surrounds the radiation passage surface in lateral directions at least in places and a cover covering the radiation passage surface and the housing top surface at least in places, wherein the cover is configured to be partially removed such that the radiation passage surface is at least partially exposed and the housing top surface remains covered at least in places by a remainder of the cover.

### CROSS-REFERENCE TO RELATED APPLICATIONS

This patent application is a national phase filing under section 371 of PCT/EP2022/070471, filed Jul. 21, 2022, which claims the priority of German patent application 102021119709.0, filed Jul. 29, 2021, each of which is incorporated herein by reference in its entirety.

### TECHNICAL FIELD

An arrangement, an optoelectronic component and a method of assembling an optoelectronic component are disclosed.

### SUMMARY

Embodiments provide an arrangement with an optoelectronic component which enables the optoelectronic component to be mounted in a particularly gentle manner. Further embodiments provide a corresponding method for assembling an optoelectronic component and a corresponding optoelectronic component.

According to at least one embodiment of the arrangement, the arrangement comprises an optoelectronic component. The optoelectronic component is, for example, a radiation-emitting or a radiation-receiving component. For example, the optoelectronic component may be a light-emitting diode, a laser diode or a photodiode.

The optoelectronic component comprises a housing that can be formed, for example, with a plastic material such as a thermoset and/or a ceramic material. The housing surrounds, for example, at least one optoelectronic semiconductor chip in a lateral direction. The lateral direction is a direction that runs parallel to a main extension direction of the optoelectronic component. The semiconductor chip can be arranged in a cavity of the housing, which can be surrounded by at least one wall of the housing.

The housing has a housing top surface on its top side. The top side is the side that also comprises a radiation passage surface of the optoelectronic component, through which electromagnetic radiation to be generated or detected in the optoelectronic component during operation leaves or enters the component.

The housing top surface surrounds the radiation passage surface in lateral directions and closes off a wall of the housing towards the top, for example. It is possible for the housing top surface to protrude beyond the radiation passage surface in a vertical direction, which can be perpendicular to the lateral direction and to the radiation passage surface, or to be flush with the radiation passage surface. The radiation passage surface can be an imaginary surface through which the electromagnetic radiation to be generated or detected in the optoelectronic component leaves the component during operation. It is also possible that the radiation passage surface is formed, at least in places, by the outer surface of a potting body or a cover plate for the at least one optoelectronic semiconductor chip.

According to at least one embodiment, the arrangement comprises a cover that covers the radiation passage surface and the housing top surface at least in places. For example, it is possible for the cover to partially or completely cover the optoelectronic component on its top side, i.e. the side on which the housing top surface and the radiation passage surface are also arranged. The cover can also protrude laterally over the optoelectronic component at least in places on the surface. The cover is, for example, partially or completely opaque. It is also possible for the cover to be opaque in places and transparent and translucent in places.

According to at least one embodiment of the arrangement, the cover is configured to be partially removed such that the radiation passage surface is at least partially uncovered by the cover and the housing top surface remains covered by a remainder of the cover, at least in places. This means that the cover is configured in such a way that, for example, the cover is partially removed before the optoelectronic component is properly operated. For example, the cover is partially or completely removed over the radiation passage surface so that the cover no longer covers the radiation passage surface or only covers it to a small extent. A remainder of the cover remains on the optoelectronic component after removal and is at least partially connected to the housing top surface. In particular, the remainder of the cover is cohesively bonded to the housing top surface, so that the remainder of the cover can be detached, in particular by destroying it.

According to at least one embodiment of the arrangement, the cover is configured to be partially and permanently removed. The radiation passage surface is partially and permanently exposed by the cover and the housing top surface remains covered, at least in places, by a remainder of the cover. In particular, this means that the cover is permanently removed from the radiation passage surface. In particular, the cover is then no longer part of the arrangement at the radiation passage surface. A remainder of the cover may remain in areas other than the radiation passage surface.

According to at least one embodiment of the arrangement, the arrangement comprises an optoelectronic component with a radiation passage surface and a housing top surface which surrounds the radiation passage surface in lateral directions at least in places, and a cover which covers the radiation passage surface and the housing top surface at least in places, wherein the cover is arranged to be partially removed such that the radiation passage surface is at least partially exposed and the housing top surface remains covered by a remainder of the cover at least in places.

The arrangement is based on the following considerations, among others. For optoelectronic components, it may be useful for the component to be protected from contamination until it is attached, for example soldered on at a destination. Furthermore, it may be useful for optoelectronic components to protect the housing body, which is made of a thermoset, for example, from solar radiation even after it has been attached at its destination. For example, in the case of radiation-emitting optoelectronic components that are used as a light source in headlights, the headlight optics project a focal spot onto the housing of the optoelectronic component, which can damage the housing top surface of the housing body.

The arrangement described here is based, among other things, on the idea of combining temporary protection against contamination and permanent protection of the housing top surface in a cover that is only partially detached from the component so that a part remains as a protective component. In this way, it is possible to dispense with a cover, which can be formed by a white silicone layer or a layer of stainless steel, for example.

According to at least one embodiment of the arrangement, the cover has a perforation which is configured to facilitate or enable partial removal of the cover. The perforation is configured, for example, as a slot punching and/or hole punching in the material of the cover and enables the part of the cover that is not to remain on the component to be separated from the remainder.

Partial removal of the cover can be further facilitated by the fact that there is an adhesive connection between the cover and the optoelectronic component only where the remainder of the cover is to remain on the housing top surface. The perforation is then arranged at the edge of the adhesive area so that the non-adhered part of the cover detaches from the optoelectronic component by mechanically pulling it off.

According to at least one embodiment of the arrangement, the cover is opaque at least in places. It is possible that the cover is completely opaque and is formed with the same material over the entire surface of the cover. The cover can, for example, be formed as a single or multi-layered metal-containing foil, in particular aluminum foil.

It is also possible for the cover to be opaque only in areas where it remains as remainder on the housing top surface. Other areas can then be made translucent. For example, markings on the optoelectronic component, which are used to identify the component, can remain visible through the cover.

According to at least one embodiment of the arrangement, the cover is configured as a self-adhesive foil, at least in places. This means that a connecting means, in particular an adhesive, for attaching the cover to the optoelectronic component may already be present on the cover before the cover is attached to the optoelectronic component. For example, those areas of the cover that remain as remainder on the optoelectronic component can be self-adhesive. Areas of the cover that are not self-adhesive can, for example, be formed with at least two layers. For this purpose, the self-adhesive part of the cover can, for example, be provided with a second foil over the radiation passage surface on the side facing the radiation passage surface, which is non-adhesive on the side facing the radiation passage surface. This ensures that the cover does not adhere to the radiation passage surface. Adhesion of the cover to the radiation passage surface could result in damage to the radiation passage surface when it is removed, which is avoided in this way.

According to at least one embodiment, the arrangement is intended to be partially removed after the optoelectronic component has been mounted at a destination. For example, the optoelectronic component may be mounted by soldering. During the soldering process, the cover provides protection against contamination. For example, the cover can prevent solder from contaminating the radiation passage surface of the component. After the soldering process, i.e. after assembling the optoelectronic component, the cover is then partially removed. The part of the cover that is no longer required can tear off in a defined manner, for example along the perforation, when it is removed.

According to at least one embodiment of the arrangement, the remainder of the cover is intended to protect an area of the housing top surface covered by the remainder from solar radiation. In other words, the cover is configured, at least in this area, such that it reflects or absorbs solar radiation sufficiently so that it cannot cause damage to the housing in the area of the housing covered by the remainder. For example, the cover in this area is formed with a metallic material such as aluminum or a plastic such as silicone or a silicone-like or hybrid material filled with radiation-scattering or radiation-reflecting or radiation-absorbing particles.

According to at least one embodiment of the arrangement, the remainder completely covers the housing top surface. In this case, the entire housing top surface is completely covered by the remainder of the cover. In this way, the housing can be protected particularly efficiently from solar radiation.

According to at least one embodiment, the remainder only covers the housing top surface in places and comprises at least two areas that are arranged at a distance from one another on the housing top surface. In this case, for example, only those areas of the housing top surface that are particularly exposed to solar radiation are permanently protected by the cover. In this way, for example, metallic material can only be applied specifically where it is needed for later use. This is particularly cost-efficient.

According to at least one embodiment of the arrangement, the cover comprises a marking for identifying the optoelectronic component on its side facing away from the housing top surface. This marking can, for example, be printed on the cover as a “unit code”, glued on or engraved, for example by means of laser radiation.

If the marking is applied to the remainder of the cover, the marking can remain even after partial removal. In the event that the marking is applied to the part of the cover that is detached from the optoelectronic component when the cover is partially removed, the marking can be particularly large and thus particularly legible on the cover.

As a further alternative, it is possible for the cover to have recesses in which, for example, the housing top surface is not covered by the cover and the marking can be read there even before the cover is partially removed.

Finally, it is also possible that the marking is only legible after partial removal of the cover and that the cover covers the marking before partial removal.

According to at least one embodiment, the arrangement comprises a further cover which is applied at least in places over the cover. For example, the cover may be arranged between the optoelectronic component and the further cover. The partial removal of the cover can then be carried out, for example, by completely removing the further cover, whereby the further cover can, for example, completely cover the cover before removal and can be bonded to the cover over its entire surface, for example by adhesive.

According to at least one embodiment of the arrangement, the cover comprises a first layer and a second layer, wherein the first layer is arranged between the housing top surface and the second layer and wherein after partial removal of the cover at least a part of the first layer remains as remainder. For example, the second layer can completely cover the optoelectronic component and the first layer. After the second layer has been removed, the radiation passage surface is then exposed, with the first layer remaining on the housing top surface, for example as protection against solar radiation. In this case, perforation can be dispensed with, for example. The first layer can, for example, be configured as a radiation-impermeable layer, such as a metal-containing foil, in particular aluminum foil. The second layer can comprise or be a transparent, self-adhesive foil.

Embodiments disclose a method for assembling an optoelectronic component. All features disclosed for the arrangement are also disclosed for the method for assembling an optoelectronic component and vice versa. In the method, an arrangement described herein is first provided. The arrangement is then mounted at a destination. The assembly can be carried out, for example, by soldering the optoelectronic component at the destination. Finally, the cover is partially removed so that the radiation passage surface of the optoelectronic component is at least partially exposed and the housing top surface remains at least partially covered by a remainder of the cover. In this way, the cover protects the optoelectronic component during assembly, for example from soiling of the radiation passage surface. The remainder of the cover on the component can, for example, serve as protection against solar radiation.

Further embodiments disclose an optoelectronic component. All the features described for the arrangement and the method for assembling an optoelectronic component are also disclosed for the optoelectronic component and vice versa. The optoelectronic component has a radiation passage surface and a housing top surface which surrounds the radiation passage surface in lateral directions at least in places. Furthermore, the optoelectronic component has the remainder of a cover which covers the housing top surface at least in places, the remainder of the cover having traces of a perforation at one edge. That is, the remainder of the cover is produced by partially removing the cover along a perforation.

In the following, the arrangement described herein, the method described herein and the optoelectronic component described herein are explained in more detail with reference to exemplary embodiments and the associated figures.

### BRIEF DESCRIPTION OF THE DRAWINGS

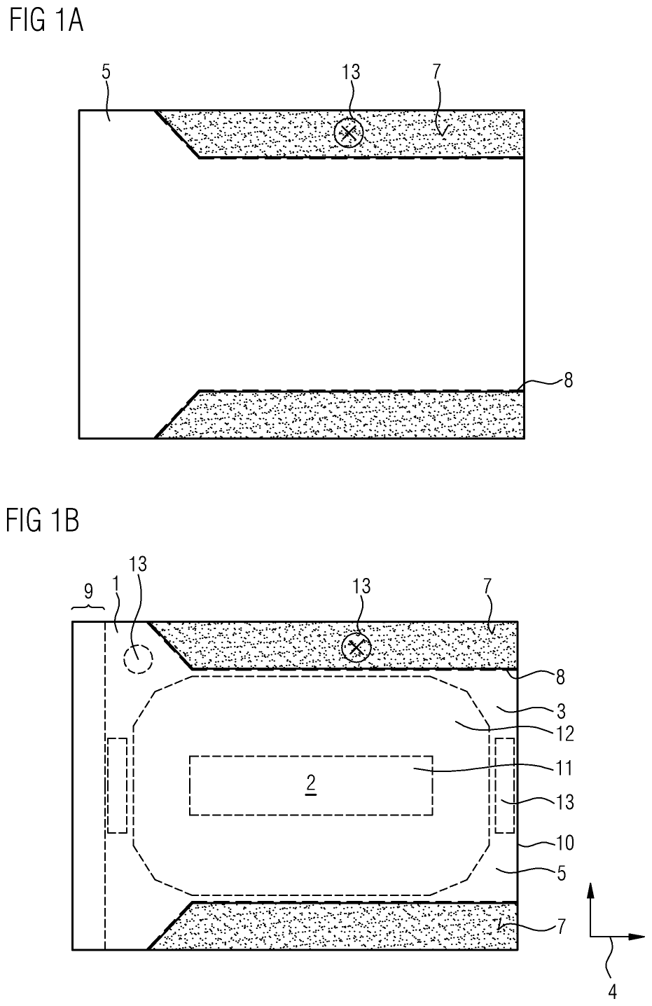

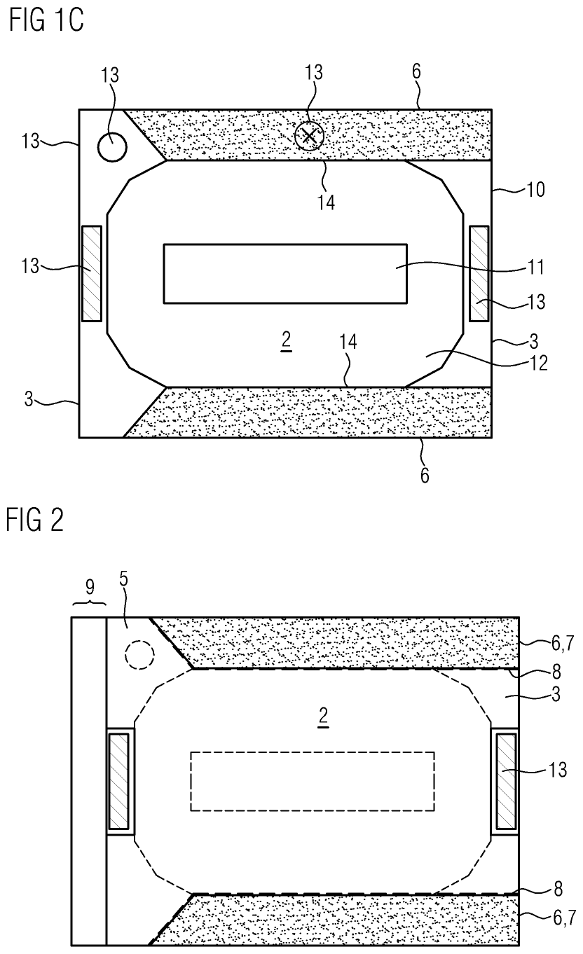

The schematic views of FIGS. 1A, 1B, 1C, 2, 3A, 3B, 4A, 4B, 5A, 5B, 5C, 5D, 6A, 6B, 6C illustrate in more detail exemplary embodiments of the arrangements, methods and optoelectronic components described herein.

### DETAILED DESCRIPTION OF ILLUSTRATIVE EMBODIMENTS

Elements that are identical, similar or have the same effect are marked with the same reference symbols in the figures. The figures and the proportions of the elements shown in the figures are not to be regarded as being to scale. Rather, individual elements may be shown in exaggerated size for better visualization and/or better comprehensibility.

With reference to the schematic sectional views of FIGS. 1A to 1C, a first exemplary embodiment of an arrangement described herein as well as a method described herein and an optoelectronic component described herein are explained in more detail.

FIG. 1A shows a schematic top view of an arrangement described here. FIG. 1B shows a schematic top view of the arrangement, with the cover 5 shown transparent. FIG. 1C shows a schematic top view of an optoelectronic component described herein.

The arrangement comprises an optoelectronic component 1 with a radiation passage surface 2 and a housing top surface 3, which is part of a housing 10.

The housing top surface 3 surrounds the radiation passage surface 2 in the lateral directions 4.

The cover 5 is opaque in the present case and comprises, for example, a metal-containing foil, such as an aluminum foil.

The optoelectronic component 1 has the housing 10 in whose cavity 12 a semiconductor chip 11, for example a light-emitting diode chip, is arranged.

Markings 13 are applied to the outside of the housing 10, in particular on the housing top surface 3, which can serve to identify and/or orient the component. Alternatively or additionally, it is possible that a marking 13 is applied to a side of the cover 5 facing away from the optoelectronic component 1. For example, in the area of a remainder 6 that remains on the housing top surface 3 after partial removal of the cover 5.

The cover 5 protrudes over the optoelectronic component 1 in the lateral direction 4 and has a tab 9 there. A tool such as tweezers, for example, can be used to partially remove the cover from the tab 9.

The cover 5 is attached to the optoelectronic component 1 in the area of an adhesive surface 7. The adhesive surface 7 is connected to the remainder of the cover 5 via a perforation 8. After partial removal of the cover 5, see FIG. 1C, the remainder 6 of the cover 5 remains on the housing top surface 3, where the remainder 6 of the cover 5 protects the housing 10 from solar radiation, for example.

After removing the cover 5, areas of the housing top surface 3, for example comprising a marking 13, may be exposed.

In the exemplary embodiment of FIG. 1C, two remainders 6 remain on the housing top surface, which are cohesively attached to the housing top surface 3 at a distance from each other. At the edge, where the perforation 8 extends before the cover is detached, the remainders 6 each have traces 14 of a perforation.

The schematic top view of FIG. 2 shows a further exemplary embodiment of an arrangement described here. In contrast to the arrangement of FIGS. 1A to 1C, the arrangement there has a recess in the area of the marking 13 on the housing top surface 3, so that, for example, a marking 13 generated by laser remains visible even before the cover is partially removed.

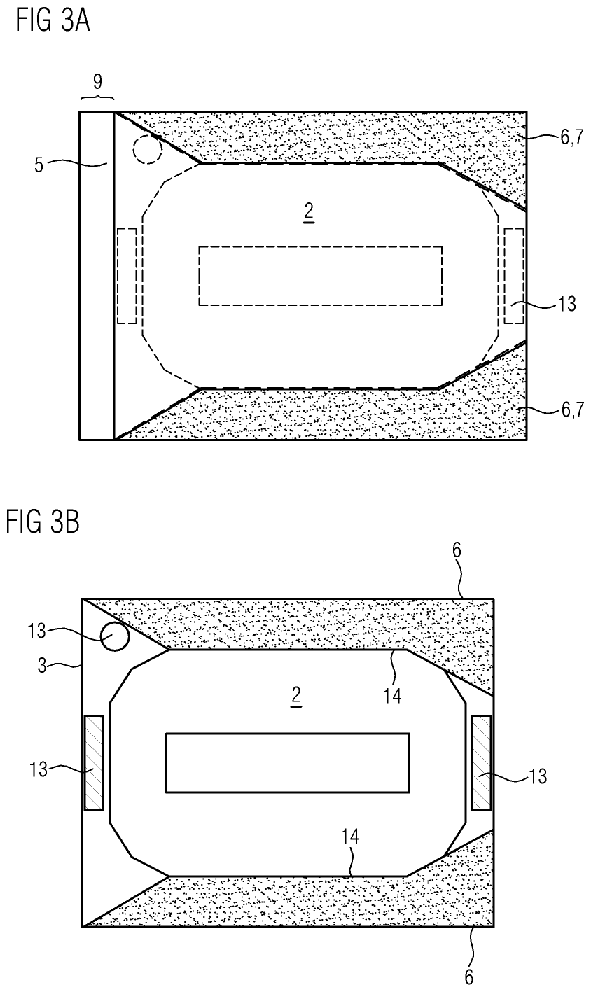

In conjunction with the schematic top view of FIG. 3A, a further exemplary embodiment of an arrangement described here is explained in more detail. FIG. 3B shows an optoelectronic component after partial removal of the cover 5. In contrast, for example, to the exemplary embodiment of FIGS. 1A to 1C, the adhesive surface 7 and thus the remainder 6 covers a larger part of the housing top surface 3.

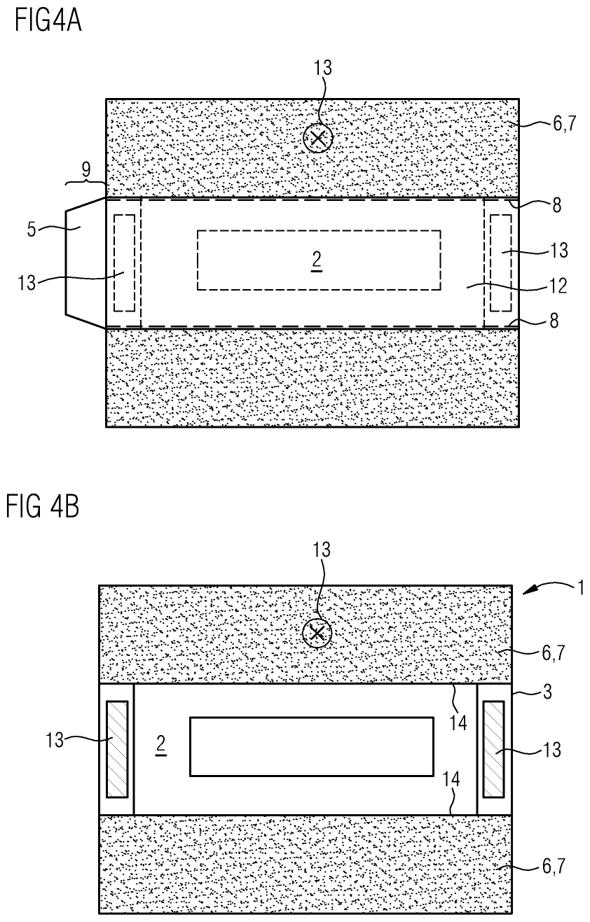

In connection with the schematic views of FIGS. 4A and 4B, a further exemplary embodiment of an arrangement described herein and a further exemplary embodiment of an optoelectronic component described herein are explained in more detail. In contrast to the previous embodiments, the adhesive surface 7 and thus the remainder 6 of the cover 5 covers not only the housing top surface 3 but also part of the cavity 12 of the optoelectronic component. The remainder 6 of the cover 5 thus also forms an aperture for the electromagnetic radiation to be emitted or detected in the optoelectronic component. In this way, the remainder 6 forms an optical component of the radiation-emitting component. Only in the area of the markings 13 does the housing top surface 3 remain free of a remainder 6 of the cover.

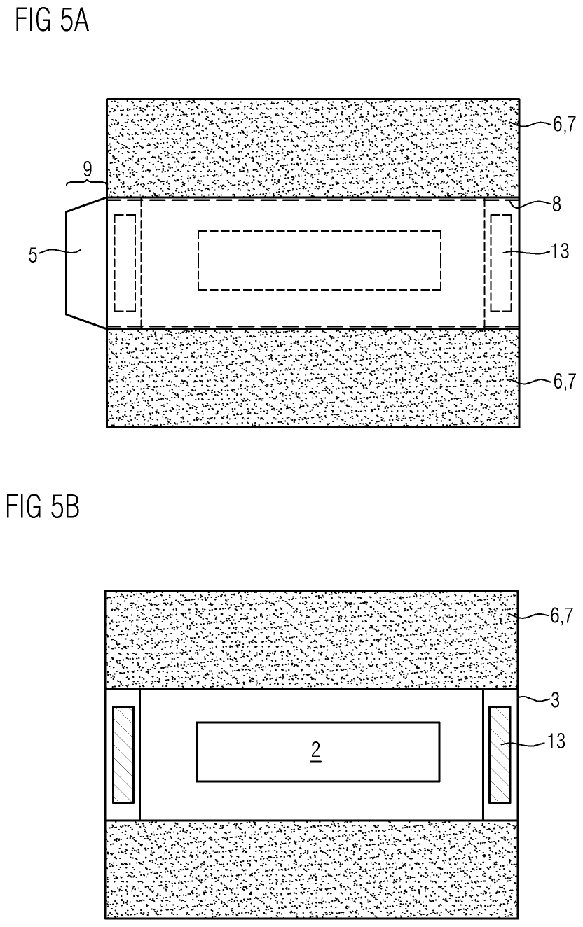

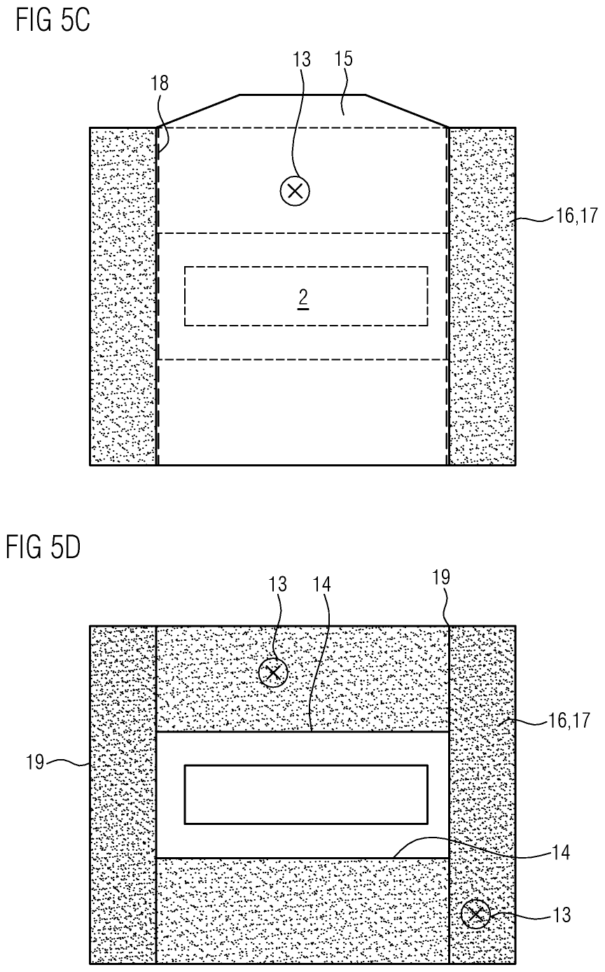

In connection with FIGS. 5A to 5D, a further exemplary embodiment of an arrangement described herein and a further exemplary embodiment of an optoelectronic component described herein are explained in more detail by means of schematic views.

In this exemplary embodiment, a further cover 15 is applied in addition to the cover 5. For this purpose, the cover 5 is first applied and partially removed, see FIGS. 5A and 5B. The further cover 15 is then applied transversely to the cover 5, see FIGS. 5C and 5D. In this way, it is also possible to cover previously uncovered areas of the housing top surface 3 with a further remainder 16 of the further cover 15. In this case, the further cover 15 is connected to the optoelectronic semiconductor component 1 via a further adhesive surface 17. A further remainder 16 can be produced via a further perforation 18 when the further cover 15 is partially detached. The further remainder 16 can have a further remainder 19 of a further perforation. A marking 13 can be present either on the remainder 6 and/or on the further remainder 16 or, for example greatly enlarged, on the further cover 15.

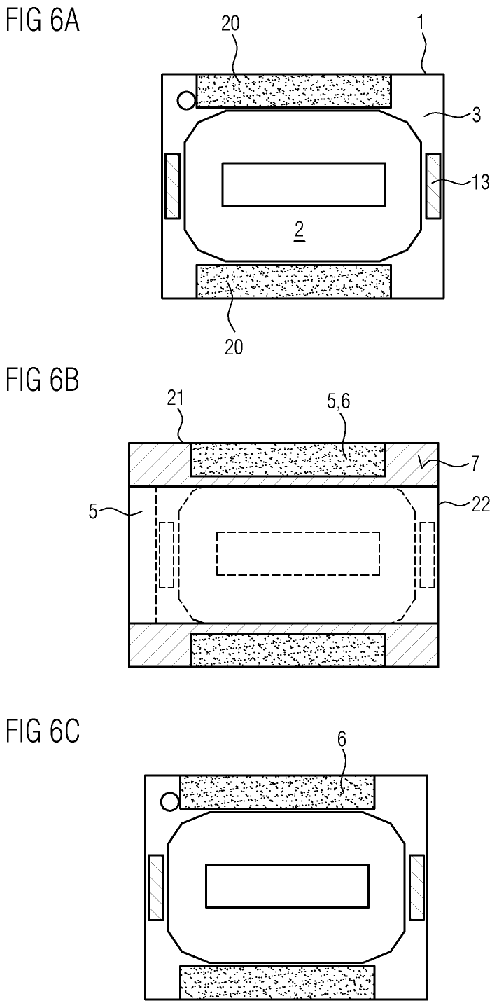

In connection with FIGS. 6A to 6C, a further exemplary embodiment of an arrangement described here and of an optoelectronic component described here is explained in more detail by means of schematic views.

In this exemplary embodiment, an adhesive 20 is applied to the remainder 6 of a cover 5 on the housing top surface 3 of the optoelectronic component 1. The adhesive can be applied by means of stamps, for example. Subsequently, a cover 5 comprising a first layer 21 and a second layer 22 is attached to the optoelectronic component 1. The first layer 21 is arranged between the housing top surface 3 and the second layer 22. The first layer 21 is formed, for example, by a metallic foil, such as an aluminum foil, which covers the optoelectronic component 1 only in the area of the adhesive 20.

After partial removal of the cover 5, i.e. peeling off the second layer 22, at least part of the first layer 21 remains as remainder 6 on the housing top surface 3. The second layer 22 may be a transparent, self-adhesive foil comprising adhesive surfaces 7, for example outside the radiation passage surface 2.

The arrangement described herein, the optoelectronic component described herein and the method described herein are characterized by the following advantages, among others.

Instead of two gluing steps with corresponding adjustment and curing of the adhesive, only one gluing step is required to attach the arrangement and thus to attach the remainder of the arrangement, which serves as protection against sunlight, for example.

Furthermore, there is no need for an expensive stainless steel screen as sun protection, as this can be formed by part of the cover 5.

When using a metallic foil as cover 5, the problem of electrostatic charging of a cover formed with plastic does not occur. This charge normally makes alignment difficult due to electrostatic attraction between the optoelectronic component and the cover. Furthermore, the risk of deformation and sagging of the cover from the housing top surface 3 to the radiation passage surface 2 is reduced.

In the arrangement described here, the cover can be attached cohesively, particularly in areas where the cover is to remain on the optoelectronic component. The other areas of the cover can be free of adhesive, which prevents unwanted areas of the cover from remaining on the optoelectronic component.

The cover 5 can be multi-layered and can be formed, for example, as a laminate of a plastic foil with an aluminum foil.

A metal-containing foil as a cover, for example an aluminum foil, is technically easy to write on, so that an individual marking 13 for the optoelectronic component or other information, for example a marking for the orientation of the component at its destination, can be applied to the cover 5. In the event that the marking 13 is applied to areas of the cover 5 that are detached during partial removal, the marking 13 does not have to be permanently durable and can therefore be made particularly cost-effectively.

It is also possible to form the cover 5 with recesses for a marking 13, which is attached to the housing 10 of the optoelectronic component 1. In contrast to an embodiment with a protective layer of white silicone on the housing top surface, for example, the marking 13 remains legible in this way.

In addition, a metal-containing foil can also provide mechanical protection for the component and can, for example, be less sensitive to chemical and mechanical stress than a protective layer made of a plastic such as silicone.

Compared to a stainless steel cover, which could be used to protect against solar radiation, a metal-containing foil, such as an aluminum foil, is much thinner and can only be applied to those areas of the component where it is needed to protect against a sunburn, for example. This results in reduced mechanical stresses in the event of temperature fluctuations. The risk of the optoelectronic component bending during use is thus significantly reduced and the temperature cycle stability of the component is also increased.

The invention is not limited to the description based on the embodiments. Rather, the invention includes any new feature as well as any combination of features, which includes in particular any combination of features in the patent claims, even if this feature or combination itself is not explicitly stated in the patent claims or embodiments.

1.-16. (canceled)

17. An arrangement comprising:
an optoelectronic component comprising a radiation passage surface and a housing top surface, which surrounds the radiation passage surface in lateral directions at least in places; and
a cover covering the radiation passage surface and the housing top surface at least in places,
wherein the cover is configured to be partially removed such that the radiation passage surface is at least partially exposed and the housing top surface remains covered at least in places by a remainder of the cover.

18. The arrangement according to claim 17, wherein the cover comprises a perforation configured to facilitate or enable partial removal of the cover.

19. The arrangement according to claim 17, wherein the cover is opaque at least in places.

20. The arrangement according to claim 17, wherein the cover comprises or is a metal-containing foil.

21. The arrangement according to claim 17, wherein the cover comprises or is an aluminum foil.

22. The arrangement according to claim 17, wherein the cover is formed as a self-adhesive foil at least in places.

23. The arrangement according to claim 17, wherein the cover is partially removed after assembling the optoelectronic component at a destination.

24. The arrangement according to claim 17, wherein the remainder of the cover protects an area of the housing top surface covered by the remainder from solar radiation.

25. The arrangement according to claim 17, wherein the remainder completely covers the housing top surface.

26. The arrangement according to claim 17, wherein the remainder covers the housing top surface only in places and comprises at least two regions that are arranged at a distance from one another on the housing top surface.

27. The arrangement according to claim 17, wherein the cover comprises a marking for identifying the optoelectronic component on its side facing away from the housing top surface.

28. The arrangement according to claim 27, wherein the marking is applied to the remainder of the cover.

29. The arrangement according to claim 17, further comprising a second cover arranged at least in places over the cover.

30. The arrangement according to claim 17, wherein the cover comprises a first layer and a second layer, wherein the first layer is arranged between the housing top surface and the second layer, and wherein, after partial removal of the cover at least a part of the first layer remains as the remainder.

31. The arrangement according to claim 30, wherein the second layer comprises or is a transparent, self-adhesive foil.

32. A method for assembling the optoelectronic component, the method comprising:
providing the arrangement according to claim 17;
assembling the arrangement at a destination; and
partially removing the cover in such a way that the radiation passage surface of the optoelectronic component is at least partially exposed and the housing top surface remains covered at least in places by the remainder of the cover.

33. An optoelectronic component comprising:
a radiation passage surface and a housing top surface, which surrounds the radiation passage surface in lateral directions at least in places; and
a remainder of a cover which covers the housing top surface at least in places,
wherein the remainder of the cover has traces of a perforation at an edge of the remainder.
